(19) United States
(12) Patent Application Publication
(10) Pub. No.: US 2025/0201468 A1
(43) Pub. Date: Jun. 19, 2025

(54) THREE DIMENSIONAL INDUCTOR AND METHOD OF MANUFACTURING THE SAME

(71) Applicant: Samsung Electronics Co., Ltd., Suwon-si (KR)

(72) Inventors: Sangwook HAN, Suwon-si (KR); Kyoungmin LEE, Suwon-si (KR); Kyungsoo LEE, Suwon-si (KR); Junho HUH, Suwon-si (KR)

(73) Assignee: Samsung Electronics Co., Ltd., Suwon-si (KR)

(21) Appl. No.: 18/975,244

(22) Filed: Dec. 10, 2024

(30) Foreign Application Priority Data
Dec. 18, 2023 (KR) 10-2023-0185157
Feb. 27, 2024 (KR) 10-2024-0028152

(51) Int. Cl. H01F 27/28; H01F 41/069

(52) U.S. Cl. CPC H01F 27/2828; H01F 41/069

(57) ABSTRACT

The inductor includes a substrate, a plurality of first horizontal wires above an upper surface of the substrate, a plurality of second horizontal wires above a back surface of the substrate, and a plurality of vertical wires, wherein the plurality of vertical wires connect the plurality of first horizontal wires to the plurality of second horizontal wires to form a spiral.

### CROSS-REFERENCE TO RELATED APPLICATION

This U.S. non-provisional application claims the benefit of priority under 35 U.S.C. § 119 to Korean Patent Application Nos. 10-2023-0185157, filed on Dec. 18, 2023, and 10-2024-0028152, filed on Feb. 27, 2024, in the Korean Intellectual Property Office, the disclosures of each of which are incorporated by reference herein in their entireties.

### BACKGROUND

Various example embodiments of the inventive concepts relate to an inductor, and more specifically, to an integrated circuit-type three dimensional (3D) inductor, a method of manufacturing a 3D inductor, and/or a method of using the 3D inductor in a radio frequency (RF) circuit, etc.

Inductors, together with resistors and capacitors, are essential passive devices in electrical and electronics engineering, especially in the field of communications.

While analog integrated circuits generally use resistors and capacitors, RF circuits used in communication equipment additionally require inductors. Devices using the resistors and capacitors have reduced voltage gains in high frequency ranges. However, the inductors may operate at a higher frequency while resonating with the capacitors, and since little voltage drop occurs in the inductors, the inductors may operate while providing appropriate voltage gains.

As wireless communication evolves and the amount of information to be transmitted increases, higher frequencies are used, and more high-performance devices are desired and/or required. On the other hand, there is a great need for design solutions for large-sized inductors to achieve miniaturization and integration suitable for use in portable communication devices, such as mobile phones.

In order to meet the demands for miniaturization and integration of the communication equipment, a number of passive devices are integrated on-chip, and thus, the number of devices may be reduced compared to an off-chip implementation. To this end, it is desired and/or necessary to incorporate relatively large inductors on-chip while maintaining desirable device performance including low resistance and/or high inductance, etc.

### SUMMARY

Various example embodiments of the inventive concepts provide a high-performance and/or high-efficiency inductor that may be applied to a compact integrated circuit device. According to one or more example embodiments of the inventive concepts, high-performance and/or high-quality inductors are provided.

Various example embodiments of the inventive concepts also provide a high-efficiency and/or high-performance inductor that is applied on-chip. In order to provide good and/or excellent high frequency performance, inductors having a large number of turns, a large thickness of a conductive wire, and/or large dimensions are provided. As a result, inductors with high inductance, low resistance, and/or low capacitance may be provided.

According to one or more example embodiments of the inventive concepts, there is provided a three-dimensional (3D) inductor including a substrate, and at least one spiral, the at least one spiral including, a plurality of first horizontal wires on an upper surface of the substrate, a plurality of second horizontal wires on a back surface of the substrate, and a plurality of vertical wires, the plurality of vertical wires being connected to the plurality of first horizontal wires and the plurality of second horizontal wires.

According to one or more example embodiments of the inventive concepts, there is provided a method of manufacturing a three-dimensional (3D) inductor, the method including forming at least one spiral on a substrate, the forming the at least one spiral including, forming a plurality of first horizontal wires on a first surface of the substrate, forming a plurality of second horizontal wires on a second surface of the substrate, and connecting the plurality of first horizontal wires to the plurality of second horizontal wires using a plurality of vertical wires, the plurality of vertical wires passing through the substrate.

According to one or more example embodiments of the inventive concepts, there is provided a three-dimensional (3D) inductor including a plurality of substrates including a first substrate and a second substrate stacked on each other, the first substrate at an uppermost position of the plurality of substrates and the second substrate at a lowermost position of the plurality of substrates, a rear surface of the first substrate being adjacent to a rear surface of the second substrate, and at least one spiral, the at least one spiral including, two terminals, a plurality of first horizontal wires on a front surface of the first substrate, a plurality of second horizontal wires on a front surface of the second substrate, and a plurality of vertical wires extending in a vertical direction, the plurality of vertical wires connected to the first horizontal wires and the second horizontal wires.

According to one or more example embodiments of the inventive concepts, there is provided a multi-chip package including a plurality of substrates including a first substrate and a second substrate stacked on each other, the first substrate at an uppermost position of the plurality of substrates and the second substrate at a lowermost position of the plurality of substrates, a rear surface of the first substrate being adjacent to a rear surface of the second substrate, a three-dimensional (3D) inductor including at least one spiral, the at least one spiral including two terminals, a plurality of first horizontal wires, a plurality of second horizontal wires, and a plurality of vertical wires, the plurality of first horizontal wires on a front surface of the first substrate, the plurality of second horizontal wires on a front surface of the second substrate, and the plurality of vertical wires connected to the first horizontal wires and the second horizontal wires, the plurality of vertical wires extending in a vertical direction, and a motherboard on which the plurality of substrates and the 3D inductor are mounted.

According to one or more example embodiments of the inventive concepts, there is provided dual three-dimensional (3D) inductors including a substrate, a first 3D inductor including at least one first spiral, the at least one first spiral including, two first terminals, a plurality of first horizontal wires, a plurality of second horizontal wires, and a plurality of first vertical wires, the plurality of first horizontal wires on an upper surface of the substrate, the plurality of second horizontal wires on a back surface of the substrate, and the plurality of first vertical wires connected to the plurality of first horizontal wires and the plurality of second horizontal wires, and a second 3D inductor including at least one second spiral, the at least one second spiral including, two second terminals, a plurality of third horizontal wires, a plurality of fourth horizontal wires, and a plurality of second vertical wires, the plurality of third horizontal wires on the upper surface of the substrate, the plurality of fourth horizontal wires on the back surface of the substrate, and the plurality of second vertical wires connected to the plurality of third horizontal wires and the plurality of fourth horizontal wires.

### BRIEF DESCRIPTION OF THE DRAWINGS

Various example embodiments of the inventive concepts will be more clearly understood from the following detailed description taken in conjunction with the accompanying drawings in which:

FIGS. 1A and 1B respectively show a perspective view and a top view of a planar spiral inductor;

FIG. 2 shows a schematic perspective view of the planar spiral inductor;

FIGS. 3A to 3C respectively show a perspective view, a front view, and a side view of a vertical inductor according to at least one example embodiment;

FIG. 4 shows a schematic perspective view of a three-dimensional (3D) inductor according to at least one example embodiment;

FIGS. 5A to 5C are schematic views of vertical inductors according to some example embodiments when viewed from above;

FIGS. 6A and 6B show horizontal wires, vertical wires, and connection portions therebetween according to some example embodiments;

FIG. 7A shows a chip including a 3D inductor according to at least one example embodiment;

FIG. 7B shows a chip including a 3D inductor according to at least one example embodiment;

FIG. 8A shows a package including a chip including a 3D inductor according to at least one example embodiment;

FIG. 8B shows a vertical inductor according to at least one example embodiment and a package including the vertical inductor;

FIG. 9 shows a flowchart of operations of manufacturing a 3D inductor, according to at least one example embodiment;

FIG. 10 shows an operation of forming an opening in a substrate, as part of the operations of manufacturing the 3D inductor, according to at least one example embodiment;

FIGS. 11A to 11C show schematic views of dual 3D inductors according to some example embodiments when viewed from above;

FIGS. 12A and 12B show schematic views of 3D inductors having 3 terminals according to some example embodiments when viewed from above; and

FIG. 13 shows a circuit diagram of a voltage controlled oscillator (VCO) including a vertical inductor according to at least one example embodiment of the inventive concepts.

### DETAILED DESCRIPTION

Hereinafter, various example embodiments of the inventive concepts are described with reference to the accompanying drawings.

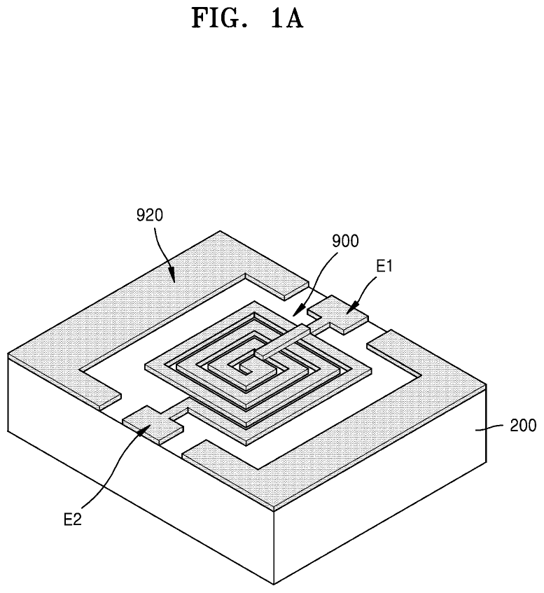

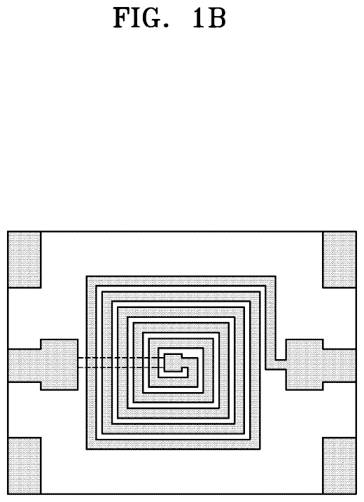

First, FIGS. 1A and 1B respectively show a perspective view and atop view of a planar coil inductor. As an inductor in an on-chip compatible with a semiconductor manufacturing process, a planar spiral inductor may be used, but the example embodiments are not limited thereto.

Referring to FIG. 1A, the planar spiral inductor includes an inductor body 900 and has a first terminal E1 connected to the inner end of a spiral (e.g., coil) and a second terminal E2 connected to the outer end of the spiral. The planar spiral inductor is above a substrate (not shown), and an interlayer insulating film 200 may be located between the substrate and the planar spiral inductor. Optionally, a metal pattern 920 may be formed around the planar spiral inductor and/or adjacent to the planar spiral inductor so as to decrease and/or prevent interference from the outside (e.g., an external source, etc.).

In the inductor body 900 of the planar spiral inductor, spirals (e.g., coils) are formed by repeatedly turning a conductive metal wire at the same level (e.g., the same vertical and/or height level, etc.). When the spirals (e.g., coils) having the same shape are formed repeatedly, the areas of the spirals vary. In other words, the area formed (e.g., enclosed, etc.) by an inner spiral is less than the area formed by an outer spiral.

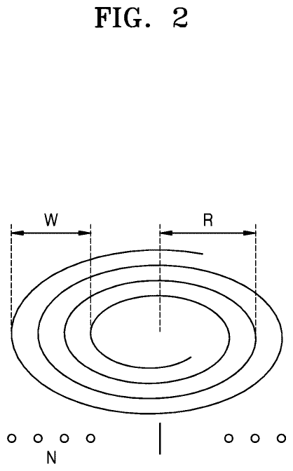

FIG. 2 is a schematic diagram of a planar spiral inductor, and the inductance L of the planar spiral inductor may be calculated using Equation 1 below.

$$L = \frac{{( N R )}^{2}}{8 R + 11 W} \qquad [ Equation 1 ]$$

In Equation 1 above, N is the number of repetitions of the spirals, R is the radius, and W is the thickness of the spirals, that is, the distance between the outermost spiral and the innermost spiral.

Examining Equation 1, as the value of W increases, that is, as the dispersion of the spiral sizes increases, the inductance L may decrease. Therefore, in order to design a high-performance inductor, R has to be increased in order to increase the overall size of the planar inductor and/or the number of repetitions N of the spirals has to be increased. However, these changes may increase the design burden of the inductor.

Also, the planar spiral inductor may be manufactured using a semiconductor process. In a wiring process during a semiconductor chip post-processing stage, the conductive metal at the same level (e.g., vertical level and/or height level, etc.) may be patterned to form spirals that turn repeatedly (e.g., increase the count and/or number of spirals included in the inductor, etc.).

However, as can be seen in FIG. 1B, the value of parasitic capacitance C with respect to the substrate may increase because the planar area of the substrate, on which the planar spiral inductor is projected (e.g., the planar spiral inductor is on and/or above, etc.), increases. Even if an interlayer insulating film is provided between the substrate and the planar spiral inductor, limitations due to capacitance (e.g., parasitic capacitance) with respect to the substrate may appear and, therefore, design complexity may increase when the physical size of the planar spiral inductor and/or the number of repetitions of spirals are increased to manufacture a high-performance inductor.

Next, the planar spiral inductor has to be equipped with an extension line for connecting the inner end of the spiral to the first terminal E1, and this extension line should pass above (see FIG. 1A) or below (see FIG. 1B) at least a portion of the inductor body 900 of the planar spiral inductor. This disturbs the symmetry of the entire inductor and causes an increase in parasitic capacitance due to the extension line. As a result, the complexity of the design may increase.

The spiral inductor having a size of hundreds of μm×hundreds of μm may be desired and/or required in order to secure the inductance of several nH or more desired and/or required for high-performance RF circuits. However, the planar spiral inductor has limitations in increasing the size and/or physical area thereof, and there is a high risk and/or increased risk of generating capacitance with respect to the substrate. In addition, it is complicated and difficult to design the planar spiral inductor to overlap with other devices. As described above, when the inductor is placed on a plane, the design thereof becomes complicated and the wiring length increases, which may increase circuit delay and/or power consumption, etc.

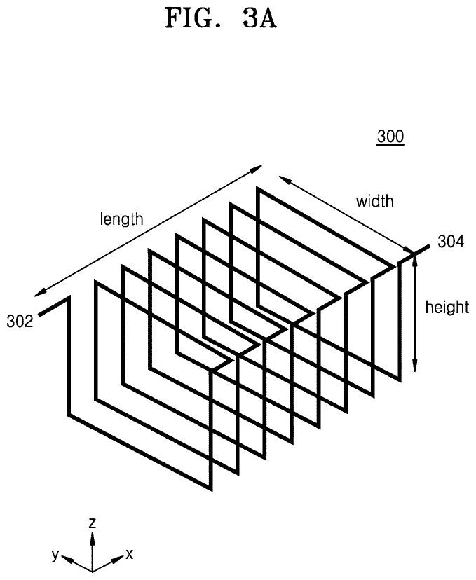

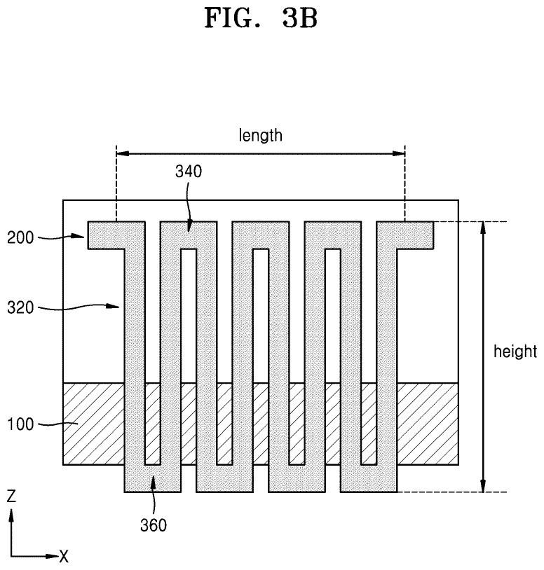

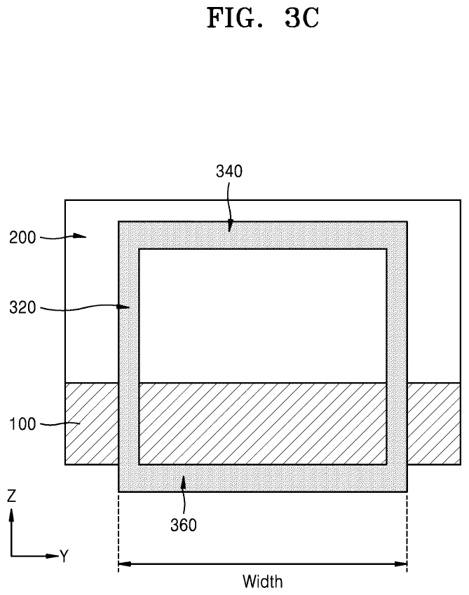

FIGS. 3A to 3C show a three-dimensional (3D) inductor 300 according to at least one example embodiment.

Among the diagrams, FIG. 3A is a perspective view of the 3D inductor 300 according to at least one example embodiment, and the 3D inductor 300 may have the length extending in an X direction, the width in a Y direction, and the height in a Z direction. The 3D inductor 300 may have a first terminal 302 and a second terminal 304 at either of the two ends of the 3D inductor 300, but is not limited thereto. Herein, the 3D inductor may also be referred to as a vertical inductor, but is not limited thereto.

Referring to FIG. 3A, for example, the shape of the vertical inductor 300 may form quadrangular projection planes by the width and height thereof, and these quadrangular projection planes may all be the same repeatedly, but the example embodiments are not limited thereto, and for example, the vertical inductor 300 may have different shapes, sizes, and/or number of spirals, etc. If the width and height of the vertical inductor 300 are expanded, the quadrangular projection plane may be expanded. If the number (N) of spirals of the vertical inductor 300 increases, the length of the vertical inductor 300 may increase.

In some example embodiments, the first terminal 302 and the second terminal 304 are respectively connected to ends of spirals opposite to each other, and thus, an extension line entering the inside of the spirals is not required. Therefore, even if the vertical inductor is designed to have many spirals, the design of the vertical inductor does not become more complex and does not affect the magnetic field distribution.

FIG. 3B is a diagram of the vertical inductor 300 according to at least one example embodiment when viewed in the Y direction. Referring to FIG. 3B, a substrate 100 may be provided, and the vertical inductor 300 may include a plurality of first horizontal wires 340 above (and/or on) an upper surface of the substrate 100, a plurality of second horizontal wires 360 on a back surface (or a rear surface) of the substrate 100, and a plurality of vertical wires 320, etc., but is not limited thereto. In some example embodiments, the first terminal 302 may connect to one of the plurality of first horizontal wires 340, and the second terminal 304 may connect to another one of the plurality of first horizontal wires 340. The plurality of vertical wires 320 may connect the plurality of first horizontal wires 340 to the plurality of second horizontal wires 360. Accordingly, the plurality of first horizontal wires 340, the plurality of second horizontal wires 360, and the plurality of vertical wires 320 may form a single conductive wire.

In some example embodiments, the plurality of first horizontal wires 340 are at the same level, and the first horizontal wires 340 may be at least partially parallel (e.g., a portion of one of the first horizontal wires 340 being parallel to a portion of another of the first horizontal wires 340) to each other, but are not limited thereto. Referring to FIG. 3A, the plurality of first horizontal wires 340 may include portions parallel to the Y direction and portions extending in the X direction and respectively connected to the plurality of vertical wires 320, but are not limited thereto. In this case, the plurality of second horizontal wires 360 may be at the same level and parallel to each other.

In some example embodiments, the plurality of second horizontal wires 360 are at the same level, and the second horizontal wires 360 may be at least partially parallel (e.g., a portion of one of the first horizontal wires 340 being parallel to a portion of another of the first horizontal wires 340) to each other, but the example embodiments are not limited thereto. Unlike what is shown in FIG. 3A, the second horizontal wires 360 may include portions parallel to the Y direction and portions extending in the X direction and respectively connected to the vertical wires 320, etc. In this case, the plurality of first horizontal wires 340 may be at the same level and parallel to each other.

In some example embodiments, the plurality of first horizontal wires 340 may be spaced apart from each other by certain and/or desired intervals, and/or the plurality of second horizontal wires 360 may also be spaced apart from each other by certain and/or desired intervals.

In some example embodiments, the plurality of vertical wires 320 may be divided into vertical wires at the front as shown in FIG. 3A, e.g., arranged relatively in the −Y direction (and may be referred to herein as a “front group”) and vertical wires at the rear as shown in FIG. 3A, e.g., arranged relatively in the +Y direction (and may be referred to herein as a “rear group”). Also, the vertical wires 320 may connect the first horizontal wires 340 to the second horizontal wires 360.

The plurality of vertical wires 320 may extend perpendicular to the substrate 100 as shown in FIG. 3B and may vertically pass through the interlayer insulating film 200 (and/or the interlayer insulating layer) and the substrate 100 as shown in FIG. 3B, but the example embodiments are not limited thereto.

Also, the plurality of vertical wires 320 may have the same height (e.g., the length in a lengthwise direction) and may be parallel to each other, but are not limited thereto. In some example embodiments, the vertical wires 320 in the front group, among the plurality of vertical wires 320, may be spaced apart from each other at certain and/or desired intervals and/or the vertical wires 320 in the rear group may also be spaced apart from each other at certain and/or desired intervals.

FIG. 3C is a side view of the vertical inductor 300 according to at least one example embodiment when viewed in the X direction. When viewed in the X direction, the first horizontal wire 340, the second horizontal wire 360, and the two vertical wires 320 form a quadrangular area, but the example embodiments are not limited thereto, and for example, the first horizontal wire 340, the second horizontal wire 360, and the two vertical wires 320 may form a different shape, etc. This area may correspond to the product of the height in FIG. 3B and the width in FIG. 3C. Accordingly, as the height of the vertical wire increases, the height of the quadrangle may increase, and as the width of the horizontal wire increases, the horizontal length of the quadrangle may increase, but the example embodiments are not limited thereto, and for example, the height and the width may be different values, may be curved, etc.

According to at least one example embodiment, unlike the height, which is subject to many semiconductor process limitations, the width and length may have a very high degree of freedom, an increased degree of freedom, and/or relatively less process limitations, etc. For example, the width and/or length may be used from several micrometers to several nanometers. However, in order to improve and/or optimize the inductance value, the length of the vertical inductor 300 may be increased while maintaining the ratio of width and height to approximately 1:1 to approximately 5:1, but the example embodiments are not limited thereto.

Also, as shown in FIG. 3B, as the number of spirals (and/or repeating spirals, etc.) increases, the length of the vertical inductor 300 increases. However, even if the number of spirals of the vertical inductor 300 increases and the length of the vertical inductor 300 increases, the area of the vertical inductor 300 horizontal to the substrate 100 does not increase significantly. Therefore, the parasitic capacitance with respect to the substrate 100 is not large. Considering the design aspect in at least one example embodiment, there is almost no limit to increasing the number of repeating spirals because there is comparatively greater freedom in selecting the length of the vertical inductor. Also, in some example embodiments, when the spacing between neighboring wires is appropriately reduced, the length of the vertical inductor may be appropriately adjusted even if the number of spirals is increased. In some example embodiments, the number N of turns of the spirals may be 3 or more, and the number N of turns of the spirals may be approximately 3 to approximately 20 in order to improve and/or optimize the inductance value, but the example embodiments are not limited thereto, and for example, there may be a greater or lesser number of turns, etc.

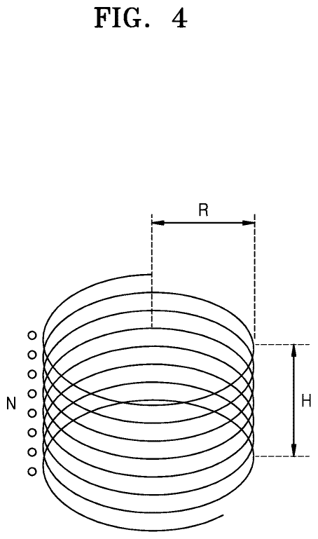

The value of inductance L of a vertical inductor having a circular projection plane as shown in FIG. 4 may be obtained by Equation 2 as follows.

$$L = \frac{{N}^{2} {R}^{2}}{9 R + 10 H} \qquad [ Equation 2 ]$$

In Equation 2, N is the number of repetitions of spirals, R is the radius, and H is the height perpendicular to the projection plane of the spirals and may correspond to the length of the vertical inductor 300 in FIG. 3A. Unlike horizontal inductors, the parameters of vertical inductors, such as the number N of repetitions, the width, the height, and/or the length, have few limitations in terms of expandability.

Specifically, the projection plane may be increased by increasing the width and/or height of the vertical inductor, the number N of repetitions of the spirals may be set to a large number, and/or the spacing between spirals may be adjusted by increasing the number N of repetitions of the spirals during design and/or fabrication, etc. As described above, the vertical inductors may have greater parameter freedom than horizontal spiral inductors and may therefore provide higher inductance, lower parasitic capacitance, smaller physical size, lower fabrication cost, etc.

Accordingly, in terms of inductor design and parameter selection, various types of vertical inductors may be provided.

For example, in some example embodiments, the first horizontal wires and the second horizontal wires may not be parallel to each other, etc. In other example embodiments, the first horizontal wires and the second horizontal wires may be parallel to each other, etc.

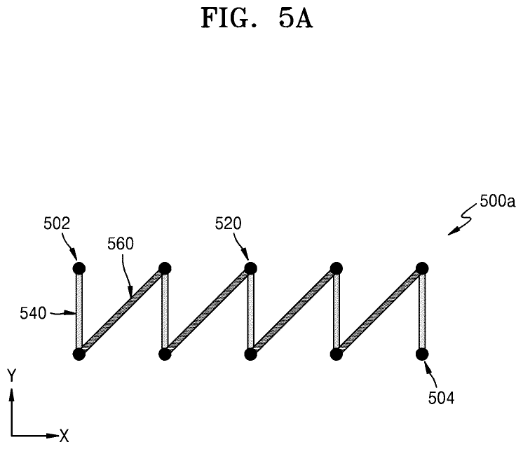

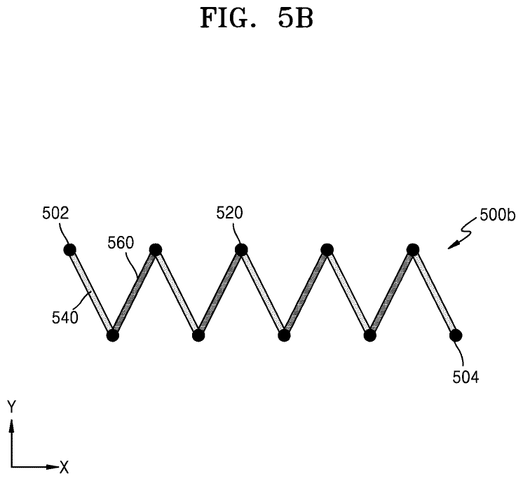

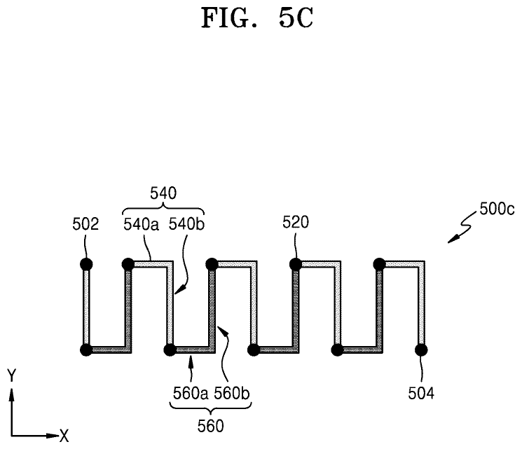

FIGS. 5A to 5C are schematic views of vertical inductors 500a to 500c according to some example embodiments when viewed from above the substrate.

First, referring to FIG. 5A, the vertical inductor 500a may include a vertical wire 520, a first horizontal wire 540, and a second horizontal wire 560, etc., and may further include a first terminal 502 and a second terminal 504, but is not limited thereto.

In the vertical inductor 500a shown in FIG. 5A, the first horizontal wires 540 may be parallel to each other and the second horizontal wires 560 may be parallel to each other, but the example embodiments are not limited thereto. In some example embodiments, the first horizontal wires 540 and the second horizontal wires 560 may not be parallel to each other, etc. The first horizontal wires 540 may be arranged perpendicular to the lengthwise direction (e.g., the length direction or the X direction) of the vertical inductor 500a, but is not limited thereto.

In FIG. 5A, the first horizontal wires 540 are arranged perpendicular to the lengthwise direction of the vertical inductor 500a and the second horizontal wires 560 are arranged at an angle to the lengthwise direction of the vertical inductor 500a. However, in some example embodiments, the second horizontal wires 560 may be perpendicular to the lengthwise direction of the vertical inductor 500a and the first horizontal wires 540 may be arranged at an angle to the lengthwise direction of the vertical inductor 500a, etc.

FIG. 5B shows the vertical inductor 500b according to at least one example embodiment. As shown in FIG. 5B, the vertical inductor 500b may include a first horizontal wire 540, a second horizontal wire 560, and a vertical wire 520, and may further include a first terminal 502 and a second terminal 504, but the example embodiments are not limited thereto. Referring to FIG. 5B, the first horizontal wires 540 are parallel to each other and the second horizontal wires 560 are parallel to each other, but are not limited thereto. For example, the first horizontal wires 540 and the second horizontal wires 560 may not be parallel to each other. Also, neither the first horizontal wires 540 nor the second horizontal wires 560 may be arranged perpendicular to the lengthwise direction of the vertical inductor 500b according to some example embodiments.

FIG. 5C shows the vertical inductor 500c according to at least one example embodiment. As shown in FIG. 5C, the vertical inductor 500c may include a first horizontal wire 540, a second horizontal wire 560, and a vertical wire 520, and may further include a first terminal 502 and a second terminal 504, but is not limited thereto. Referring to FIG. 5C, first horizontal wires 540 may each include a first portion 540a parallel to the lengthwise direction of the vertical inductor 500c and a second portion 540b perpendicular to the lengthwise direction of the vertical inductor 500c, but are not limited thereto. The second portions 540b of the first horizontal wires 540 may be parallel to each other, but is not limited thereto. Each of second horizontal wires 560 may include a first portion 560a parallel to the lengthwise direction of the vertical inductor 500c and a second portion 560b perpendicular to the lengthwise direction of the vertical inductor 500c, but are not limited thereto. The second portions 560b of the second horizontal wires 560 may be parallel to each other, but is not limited thereto.

As shown in FIG. 5C, the second portions 540b of the first horizontal wires 540 may be parallel to the second portions 560b of the second horizontal wires 560, but the example embodiments are not limited thereto. Also, all of the second portions 540b of the first horizontal wires 540 and the second portions 560b of the second horizontal wires 560 may be arranged perpendicular to the lengthwise direction of the vertical inductor 500c, but are not limited thereto.

Referring back to FIGS. 3A to 3C, in some example embodiments, the vertical inductor may be formed as a single body, but is not limited thereto. For example, the vertical inductor may be formed by connecting first horizontal wires, second horizontal wires, and vertical wires to each other, etc.

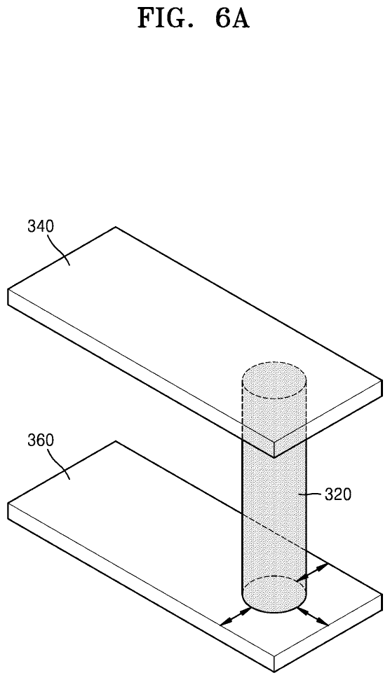

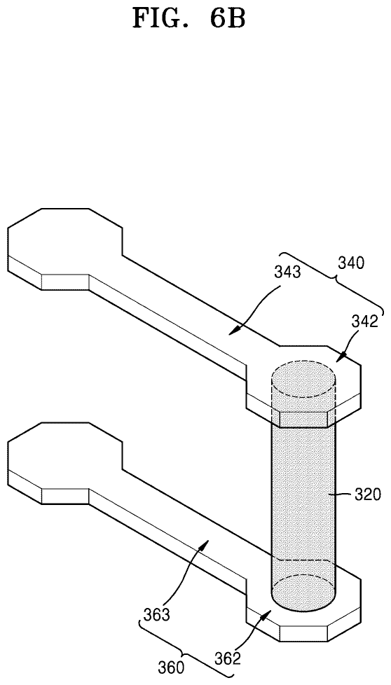

Referring to FIG. 6A, a first horizontal wire 340 and a second horizontal wire 360 may extend parallel to each other at a constant width, but are not limited thereto. A vertical wire 320 may be connected to the first horizontal wire 340 and the second horizontal wire 360. It may be advantageous to form the vertical wire 320 as a thick and/or wide wire to lower resistance of the vertical inductor. As the resistance of the vertical inductor decreases, the quality factor (Q-factor) improves. Therefore, a high-performance inductor may be provided.

In order to lower resistance of the inductor, the first and second horizontal wires 340 and 360 and the vertical wire 320 may be well matched. As shown in FIG. 6B, a first horizontal wire 340 may include a connection portion 342 and a wiring portion 343. Also, the second horizontal wire 360 may include a connection portion 362 and a wiring portion 363. The vertical wire 320 may be connected to both the connection portion 342 of the first horizontal wire 340 and the connection portion 362 of the second horizontal wire 360. To increase the area of a connection portion, the shapes of a wiring portion may be different from the shape of the connection portion, but is not limited thereto. As shown in FIG. 6B, the widths of the connection portions 342 and 362 may be greater than the widths of the wiring portions 343 and 363, but are not limited thereto.

In some example embodiments, as shown in FIG. 5C, the first portion 540a of the first horizontal wire 540, the second portions 540b of the first horizontal wires 540, the first portions 560a of the second horizontal wires 560 and the second portion 560b of the second horizontal wire 560 may each include a connection portion having a greater width than a wiring portion, and the vertical wire 520 may be connected to these connection portions, but the example embodiments are not limited thereto.

In some example embodiments, the projection planes formed by the spirals may be the same and/or substantially the same (e.g., within +/−10%, etc.). The projection plane may have a quadrangular shape, but the example embodiments are not limited thereto. Also, the horizontal wires and/or the vertical wires comprised in the vertical inductor may be arranged at desired and/or certain intervals. As shown above, if the distances between the wires and the projection planes formed by the repeated inductor spirals are kept constant, the magnetic fields generated by the wires may overlap each other appropriately. Accordingly, the inductance may be improved.

Accordingly, in the vertical inductor according to at least one example embodiment, the plurality of vertical wires may have the same height and may be parallel to each other, the plurality of first horizontal wires may be at the same level and at least partially parallel (e.g., a portion of one of the first horizontal wires 340 being parallel to a portion of another of the first horizontal wires 340) to each other, and/or the plurality of second horizontal wires may be at the same level and at least partially parallel to each other, etc.

In some example embodiments, the first horizontal wire provided above (and/or on) the upper surface of the substrate may include ultra-thick metal (UTM), but the example embodiments are not limited thereto. The UTM may be provided in the top metal layer of a chip, and the UTM has a thickness of, e.g., 3 μm or more, and may thus lower resistance, but is not limited thereto. Specifically, the thickness of the UTM may be approximately 2 μm to approximately 5 μm, but is not limited thereto. The first horizontal wire includes conductive materials and may include, but is not limited to, copper, silver, platinum, nickel, gold, tungsten, aluminum, and/or an alloy thereof, etc. Specifically, the first horizontal wire may include copper with low resistance, etc. Therefore, the desirable Q-factor may be secured.

It may be advantageous to generate larger inductance, e.g., to provide a larger projected area. In some example embodiments, vertical wires having through-silicon vias (TSVs) passing through a substrate may be used in order to increase the height of the spiral. For example, referring to FIG. 3B, the plurality of vertical wires 320 may be respectively connected to the plurality of first horizontal wires 340, extend vertically through the substrate 100, and be respectively connected to the plurality of second horizontal wires 360 on the lower surface of the substrate 100, etc. The TSV may be formed as a single body. To this end, an opening may be formed through the substrate 100 starting from the upper portion of the interlayer insulating film 200, and at least one conductive material may fill the opening. Alternatively, the opening may also be formed through the interlayer insulating film 200 starting from the lower portion of the substrate 100. In some example embodiments, a combined vertical wire may be provided, in which a first vertical wiring section formed through the interlayer insulating film 200 and a second vertical wiring section formed through the substrate 100 are combined with each other, but the example embodiments are not limited thereto.

The TSV includes conductive materials, such as W, Sn, Cu, Ag, Pt, Au, and/or an alloy thereof, but the example embodiments are not limited thereto.

The TSV has to be insulated from the substrate, and insulation between the substrate and the TSV may be achieved in various ways. For example, an insulating layer may be formed between the substrate and the TSV to isolate the substrate from the TSV, but the example embodiments are not limited thereto. The insulating layer may include an insulating film formed on the side surface of the opening that has passed through the substrate. The insulating film may include, but is not limited to, a silicon oxide film, a silicon nitride film, and/or a composite film thereof, etc. In addition to these films, various insulating films, such as metal oxide films and nitride films, may be used. Also, the insulation may be made by forming voids.

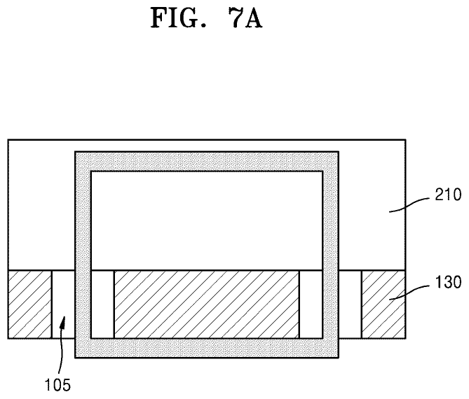

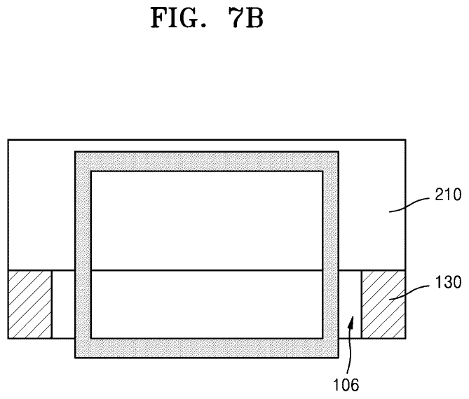

In another method of insulating the substrate from the TSV, as shown in FIG. 7A, an insulating layer may be formed in a peripheral region (or a region) 105 in which the TSV is formed. In another method, as shown in FIG. 7B, at least one region including an insulating material, that is, an insulating isolation region, may be formed entirely in a region 106 of a substrate 130, in which a vertical inductor is formed. Subsequently, vertical wires may be provided by forming openings (e.g., in at least one insulating isolation region) and filling the openings with conductive materials, etc, such that, e.g., the vertical wires may pass through the at least one insulating isolation region.

As shown in FIG. 7B, when the insulating isolation region is formed in a portion of the substrate 130 and then the opening is formed, the opening may be formed under the same or similar etching conditions. Accordingly, the process conditions may be easily set. Also, since the opening extends to the back surface of the substrate 130, the vertical wire has a high aspect ratio even if the opening is deep. Accordingly, the vertical wire having the relatively uniform thickness may be formed.

The cross-section of the vertical wire includes, but is not limited to, circular, oval, quadrangular, and/or polygonal shapes. In terms of resistance, it is advantageous for the thickness and/or diameter of the vertical wire to be increased, and for example, the thickness and/or diameter of the vertical wire may be approximately 2 μm to approximately 5 μm considering the process and design, but the example embodiments are not limited thereto.

In some example embodiments, as shown in FIG. 7A, at least a portion of the substrate 130 may be left at the center of the vertical inductor, or at least a portion of the substrate 130 may be replaced with a conductive material, but the example embodiments are not limited thereto. In this case, the value of inductance may be adjusted.

In some example embodiments, the height of the vertical inductor may be approximately 20 μm to approximately 200 μm, but is not limited thereto.

In some example embodiments, the front surface and/or back surface of a substrate may be removed in advance before forming at least one vertical wire that vertically passes through the substrate. The height of the substrate is not limited, but the height (or the thickness) of the substrate may be approximately 50 μm or less considering the aspect ratio of the vertical wire, but is not limited thereto.

In some example embodiments, a second horizontal wire may include at least one wire provided on the lower surface of a substrate and, specifically, may include a redistribution layer and/or a backside metal (BSM) layer. It is advantageous to increase the thickness of the second horizontal wire in order to lower the resistance, and for example, the thickness of the second horizontal wire may be approximately 2 μm to approximately 5 μm in terms of chip design and process, but the example embodiments are not limited thereto.

In order to effectively transmit power to a chip, a backside power delivery network (BS-PDN) is formed on the back surface of the substrate, but the example embodiments are not limited thereto. The wiring layer formed in this case may be referred to as a BSM layer. The second horizontal wire may be formed in this BSM layer, but is not limited thereto.

In some example embodiments, a chip (or a chiplet) package may be provided, in which a chip including the vertical inductor according to at least one example embodiment of the inventive concepts, another RF chip (or a chiplet), another logic chip (or a chiplet) and/or another memory chip (or a chiplet) are mounted together.

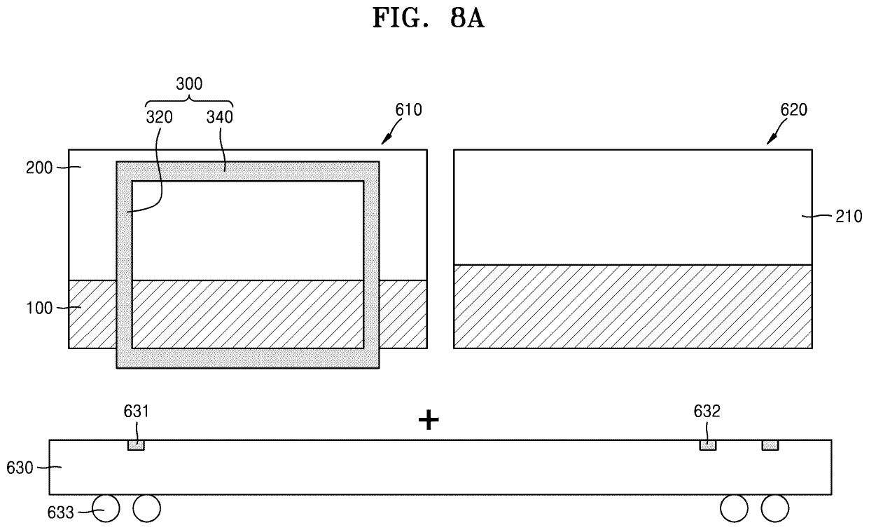

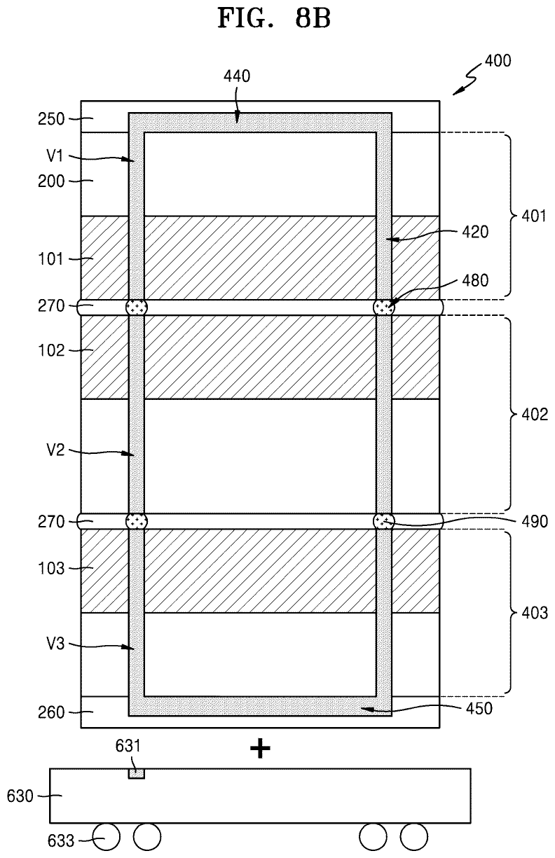

Referring to FIG. 8A as an example, a chip (or a chiplet) 620 is provided, which is different from a chip (or a chiplet) 610 including the vertical inductor 300 according to at least one example embodiment. A package may be formed by mounting at least two chips (or chiplets) 610 and 620 at designated locations on a motherboard 630, but the example embodiments are not limited thereto. The motherboard 630 may have conductive layer patterns 631 and 632 on the upper surface thereof, and the conductive layer patterns 631 and 632 may include connection points with the chips 610 and 620 to be mounted, but is not limited thereto. The motherboard 630 may have a plurality of balls 633 on the top or bottom thereof, but is not limited thereto. Also, in some example embodiments, an interposer may be provided between the motherboard 630 and the chips (or chiplets) 610 and 620 to mount the chips 610 and 620 thereon, etc.

Furthermore, the package may have a 3D stack structure, such as a 3D integrated circuit (IC)/chiplet, in a logic process, but the example embodiments are not limited thereto. When using a stack chip structure, the height of the vertical inductor may be further increased by using the stack chip structure.

FIG. 8B shows a vertical inductor and a package (e.g., semiconductor package) including the vertical inductor. A chip structure 400 in which a plurality of chips, e.g., three chips, etc., each having a semiconductor substrate are stacked on each other may be mounted on a motherboard 630, but the example embodiments are not limited thereto.

Continuing to refer to FIG. 8B, the chip structure 400 may have a structure in which a first chip 401 at the uppermost position (and may be referred to herein as an “uppermost chip”), a second chip 402 immediately below the uppermost chip 401 (and may be referred to herein as a “middle chip”), and a third chip 403 below the middle chip (and may be referred to herein as a “lowermost chip” or a “bottom chip”) are stacked, but the example embodiments are not limited thereto, and for example, there may be a greater or lesser number of chips, etc.

The uppermost chip 401 may include a first substrate 101, a first horizontal wire 440 above (and/or on) the upper surface of the first substrate 101, and a first vertical wiring section V1 connected to the first horizontal wire 440 and passing through the first substrate 101, etc.

The middle chip 402 may include a second substrate 102, and the second substrate 102 may be adjacent to the first substrate 101 of the uppermost chip 401. The middle chip 402 may include a second vertical wiring section V2 passing through the second substrate 102, etc.

The lowermost chip 403 may include a third substrate 103, and the third substrate 103 may be adjacent to the middle chip 402. The lowermost chip 403 may include a third vertical wiring section V3 passing through the third substrate 103. Also, the lowermost chip 403 may include a second horizontal wire 450 above (and/or on) the upper surface of the third substrate 103, etc.

The first vertical wiring section V1 of the uppermost chip 401 may be connected to the second vertical wiring section V2 of the middle chip 402 via at least one conductive connecting element 480, etc. The second vertical wiring section V2 of the middle chip 402 may be connected to the third vertical wiring section V3 of the lowermost chip 403 via at least one conductive connecting element 490. For example, the conductive connecting elements 480 and 490 may include a microbump and/or hybrid copper bonding (HCB), etc., but is not limited thereto. An underfill 270 and/or a molding material may be arranged between the chips to decrease and/or prevent physical damage and/or electrically protect the stacked chips. Also, passivation films 250 and 260 may be formed on the top of the chips to decrease and/or prevent physical damage and/or provide electrical protection, etc., but the example embodiments are not limited thereto. In an example embodiment, each of the first vertical wiring section V1 to the third vertical wiring section V3 may include the TSVs, such that the TSVs may pass through the substrate 101 to the substrate 103. As described above, the height of the projected area of the vertical inductor is increased by connecting the vertical wiring sections of the stacked chips to each other. Accordingly, the inductor having better Q-factor and/or inductance may be provided.

In some example embodiments, the number N of spirals of the vertical inductor in the stack chip structure may be approximately 3 to approximately 20, and the height of the vertical inductor may be approximately 40 μm to approximately 800 μm, but the example embodiments are not limited thereto, and the number of spirals and/or the height of the inductors may be greater or lesser than specified values herein. As an example, the height of each of the substrates may be 50 μm or less, and the thickness of each of the vertical wires may be approximately 2 μm to approximately 5 μm, but are not limited thereto.

As described above, in some example embodiments, the vertical inductor may include the first substrate 101 at the uppermost position (and may be referred to herein as the “uppermost substrate”) and the third substrate 103 at the lowermost position (and may be referred to herein as the “lowermost substrate”). The vertical inductor may include a plurality of substrates stacked such that the upper surface of the uppermost substrate 101 and the upper surface of each of the other substrates (e.g., the lowermost substrate 103) are arranged opposite to each other, or such that the lower surface of the uppermost substrate 101 and the lower surface of each of the other substrates (e.g., the lowermost substrate 103) are arranged adjacent to each other. The vertical inductor may also include first horizontal wires 440 formed above (and/or on) the uppermost substrate 101 among the plurality of stacked substrates, second horizontal wires 450 formed above (and/or on) the lowermost substrate 103 among the plurality of stacked substrates, and/or vertical wires 420 extending in the vertical direction and connecting the first horizontal wires 440 to the second horizontal wires 450, etc. The plurality of vertical wires 420, the plurality of first horizontal wires 440, and/or the plurality of second horizontal wires 450 may form a spiral (e.g., coil, etc.), and this spiral may be provided to, included in, and/or attached to the vertical inductor having two terminals.

As described above with reference to the diagrams, even in the stack vertical inductor shown in FIG. 8B, the second horizontal wires 450 may use the uppermost conductive wire, for example, the UTM, but the example embodiments are not limited thereto.

In some example embodiments, the two terminals connecting the vertical inductor to the outside (e.g., to an external device, etc.) may extend from the uppermost chip or from the lowermost chip. In some example embodiments, the two terminals may respectively connect to two different horizontal wires of the plurality of the first horizontal wires 440 or the plurality of the second horizontal wires 450. Accordingly, various modifications may be provided in terms of freedom of design (e.g., IC design, etc.).

In some example embodiments, the direction in which the substrates are stacked may vary. For example, the substrates may be stacked such that all front surfaces thereof face upward, but are not limited thereto. Also, an interposer may optionally be provided between the stacked chips and the motherboard 630, and another logic chip and/or memory chip may be mounted on the motherboard 630, etc.

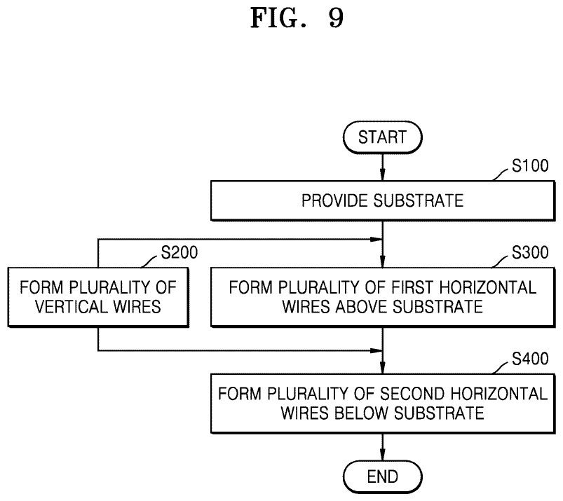

Next, a method of manufacturing a vertical inductor is described below according to at least one example embodiment. FIG. 9 is a flowchart showing operations of manufacturing a vertical inductor, but the example embodiments are not limited thereto.

Referring to FIG. 9, a substrate may be provided (S100). The substrate may include a base on which passive elements, such as resistors, capacitors, inductors, and/or other elements, such as p-type and/or n-type transistors, etc., are formed, but is not limited thereto. The substrate may include a single material semiconductor substrate and/or a compound semiconductor substrate, such as GaN, etc. The single material semiconductor substrate may include an n-type substrate doped with n-type impurities or a p-type substrate doped with p-type impurities. For example, materials forming the single material semiconductor substrate may include silicon, germanium, carbon, etc.

The substrate may include at least one semiconductor region and at least one insulator region, etc. The substrate may refer to a semiconductor wafer, for example a silicon semiconductor wafer, or to segments cut into a plurality of IC chips, etc. Also, the substrate may be in a state before a plurality of semiconductor processes are performed, or the substrate may be in a state in which elements have already been formed thereon through the semiconductor processes.

Next, a plurality of vertical wires may be formed on the substrate (S200). The vertical wires may vertically connect the first horizontal wires to the second horizontal wires and thus extend in height. For example, the vertical wires may pass through the substrate and/or an interlayer insulating film formed on the substrate, etc.

As a method of forming a vertical wire that passes through the substrate and the interlayer insulating film, there are examples of methods of forming an integrated vertical wire and a connected vertical wire.

According to at least one integrated vertical wire forming method, an opening with a large aspect ratio may be formed (and/or simultaneously formed) using an in-situ dry etching method toward the upper surface of a substrate on which an interlayer insulating film has been formed. Subsequently, the vertical wires may be formed (and/or simultaneously formed) by filling openings with conductive materials. In the at least one integrated vertical wire forming method, less misalignment occurs and resistance is reduced, and thus, excellent Q-factor may be obtained.

According to at least one connected vertical wire forming method, a TSV passing a substrate is separately formed. Then, a vertical wiring section (and/or via, contact, etc.) passing through an interlayer insulating film may be formed so as to be well aligned with the TSV. In the at least one connected vertical wire forming method, processes may be simplified, and good alignment may lower resistance generation.

In some example embodiments, in order to form at least one vertical wire, at least one first opening is formed through the substrate and filled with a sacrificial film, such as SiO₂, Si/SiO₂, etc. Then, at least one second opening is formed through an interlayer insulating film so that the second opening is aligned with the first opening, and the sacrificial film is removed. Subsequently, vertical wires may be formed by filling (and/or simultaneously filling) the first and second openings with conductive materials. However, the example embodiments are not limited to the vertical wire forming methods described above.

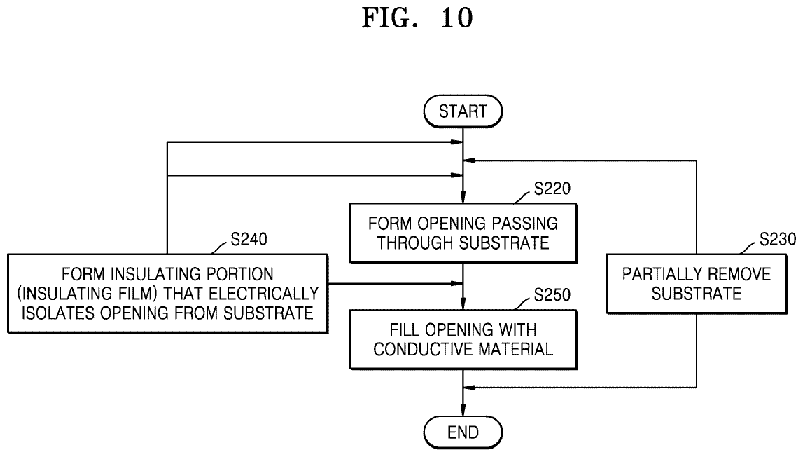

In order to electrically insulate the vertical wires from the substrate, at least one insulating film may be applied thereon. FIG. 10 shows an operation of forming an opening in a substrate, as part of the operations of manufacturing the vertical inductor, according to at least one example embodiment, but the example embodiments are not limited thereto.

Referring to FIG. 10, forming of the plurality of vertical wires on the substrate (S200) in FIG. 9 may include forming openings through the substrate (S220), forming an insulating film/insulating portion that electrically separates each of the openings from the substrate (S240), and filling the openings with conductive material (S250).

The forming of the insulating film between the opening and the substrate (S240) may include forming the insulating film on at least a side surface of the opening. The insulating film may include, but is not limited to, a silicon oxide film, a silicon nitride film, a metal nitride film, a metal oxide film, and/or a composite film thereof, but is not limited thereto.

In the at least one example embodiment described with reference to FIG. 7A, after the insulating portion is formed in the region 105 of the substrate 130, the openings passing through the region 105 may be formed to form the vertical wires.

In some example embodiments, removing a portion of the substrate (S230) may be additionally performed before or after the forming of the openings in the substrate to decrease a thickness of the substrate. As part of the substrate, the substrate may be removed (e.g., polished, grinded, etched, etc.) to a desired and/or certain thickness from the back surface thereof. Methods of removing the substrate may include chemical-mechanical polishing (CMP) and/or dry/wet etching. If the substrate is partially removed (S230), the thickness of the substrate decreases. Accordingly, the process of penetrating the substrate may be easily performed, and a TSV with a high aspect ratio may be formed.

Referring back to FIG. 9, a plurality of first horizontal wires may be formed above the substrate (S300).

The first horizontal wires may use a wiring layer above the substrate, but a thick wiring layer may be advantageous for lowering the resistance of the vertical inductor. Also, in order to generate larger inductance, the first horizontal wire provided above the upper surface of the substrate may include UTM, but is not limited thereto. The first horizontal wire includes conductive materials and may include, but is not limited to, copper, silver, platinum, nickel, gold, tungsten, aluminum, and/or an alloy thereof, etc. For example, the first horizontal wire may include copper with low resistance.

Next, a plurality of second horizontal wires may be formed below the substrate (S400). The second horizontal wire may include at least one wire provided on the lower surface of the substrate and may include, for example, a redistribution layer and/or BSM, etc. In order to lower the resistance of the vertical inductor, it may be advantageous for the second horizontal wire to be thicker. The forming of the second horizontal wires (S400) may be performed in a pre-processing operation or may be performed in a post-processing operation depending on the order of the semiconductor processes.

Also, in operation (S200) described above, the method of forming the plurality of vertical wires includes forming the vertical wires from the upper surface of the substrate, but is not limited thereto. However, in some example embodiments, the plurality of vertical wires may be formed from the back surface of the substrate, etc.

After the TSVs are formed that pass through the substrate from the back surface of the substrate, the first horizontal wires may be formed and then the second horizontal wires may be formed, but the example embodiments are not limited thereto. As described above, according to at least one example embodiment of the inventive concepts, it should be understood that the method of forming the vertical inductor includes operations S100 to S400 shown in FIG. 9, but are not limited thereto, and for example, the order of the operations may be changed, one or more operations may be omitted, added, and/or combined, etc. Also, herein, the expression in which “the vertical wires connect the horizontal wires to each other” should not be interpreted as representing or implying a process order, but should be understood to indicate that vertical wires structurally connect the horizontal wires to each other.

A variety of devices and/or integrated circuits, etc., including the vertical inductor disclosed herein may be provided. For example, a device and a circuit, such as an LC filter including a plurality of single vertical inductor having various sizes, may be provided. Additionally or alternatively, in a device and a circuit desiring and/or requiring low noise and/or high-speed signal processing, differential signals may be used as input signals. The device and/or circuit that uses such a pair of differential signals as inputs may be provided as a device and/or circuit including dual vertical inductors.

According to at least one example embodiment of the inventive concepts, the dual vertical inductors may include a substrate, a first vertical inductor, and a second vertical inductor, but is not limited thereto. The first vertical inductor may include a plurality of first horizontal wires on the upper surface of the substrate, a plurality of second horizontal wires on the back surface of the substrate, and a plurality of first vertical wires, but is not limited thereto. The plurality of first vertical wires may connect the plurality of first horizontal wires to the plurality of second horizontal wires to form a first spiral, and the first spiral may correspond to the first vertical inductor having two terminals, etc. The second vertical inductor may include a plurality of third horizontal wires on the upper surface of the substrate, a plurality of fourth horizontal wires on the back surface of the substrate, and a plurality of second vertical wires, but is not limited thereto. The plurality of second vertical wires may connect the plurality of third horizontal wires to the plurality of fourth horizontal wires to form a second spiral, and the second spiral may correspond to the second vertical inductor having two terminals, etc. The structural features and/or manufacturing methods for the first vertical inductor and the second vertical inductor may be the same as or similar to the structural features and manufacturing methods for the single vertical inductor described above with reference to the diagrams, but are not limited thereto. Therefore, descriptions of identical or similar parts are omitted.

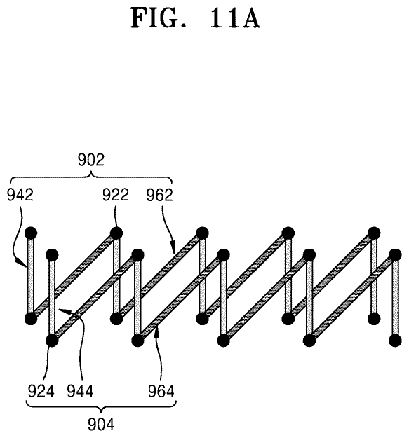

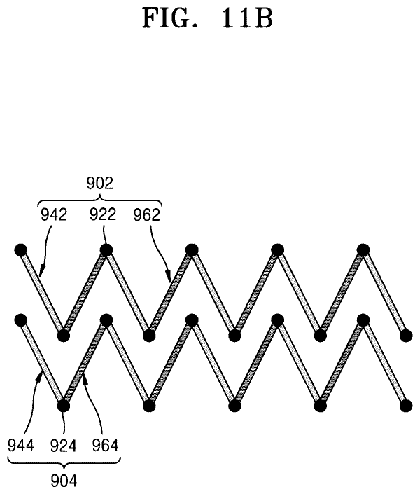

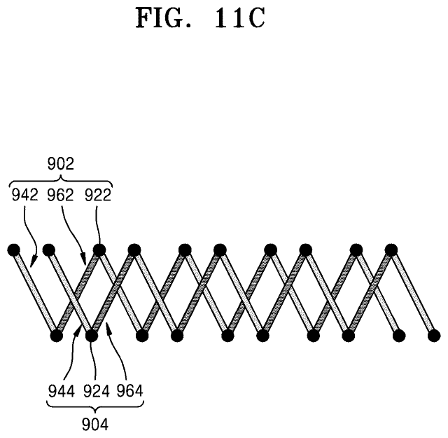

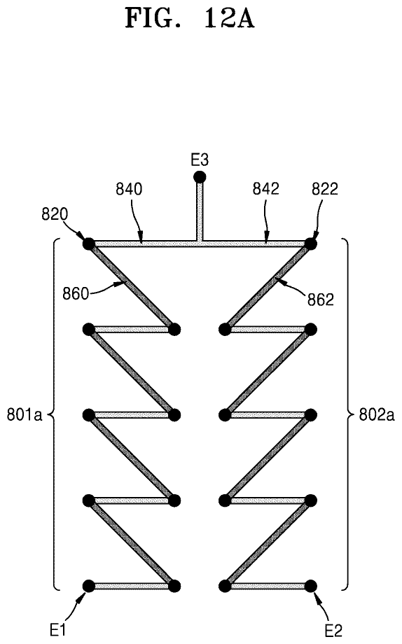

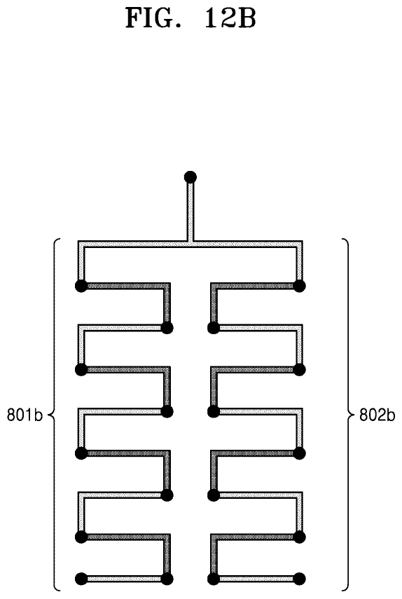

The first vertical inductor and the second vertical inductor in the dual vertical inductors may be spatially and/or magnetically coupled to each other, but are not limited thereto. For example, as shown in FIGS. 11A to 11C, when viewed from above the upper surface of a substrate, a first vertical inductor and a second vertical inductor may be parallel to each other, but are not limited thereto. In another example, as shown in FIGS. 12A and 12B, when viewed from above the upper surface of a substrate, a first vertical inductor and a second vertical inductor may be symmetrical to each other, but are not limited thereto.

Referring to FIGS. 11A to 11C, a first vertical inductor 902 and a second vertical inductor 904 may be provided, but the example embodiments are not limited thereto, and for example, a greater number of vertical inductors may be provided. A plurality of first horizontal wires 942 of the first vertical inductor 902 may be parallel to a plurality of third horizontal wires 944 of the second vertical inductor 904, but are not limited thereto. A plurality of second horizontal wires 962 of the first vertical inductor 902 may be parallel to a plurality of fourth horizontal wires 964 of the second vertical inductor 904, but are not limited thereto. A plurality of first vertical wires 922 of the first vertical inductor 902 may be parallel to a plurality of second vertical wires 924 of the second vertical inductor 904, but are not limited thereto. Therefore, the first vertical inductor 902 and the second vertical inductor 904 may be spatially parallel to each other, and the first inductance formed by the first vertical inductor 902 and the second inductance formed by the second vertical inductor 904 may create added inductance. Also, as shown in FIGS. 11A to 11C, the inductors are spatially arranged differently, thereby providing phase differences in the inductance values provided by the inductors.

Next, referring to FIGS. 12A and 12B, when viewed from above the upper surface of the substrate, the first vertical inductor and the second vertical inductor in the dual vertical inductor may be symmetrical to each other, but are not limited thereto. FIG. 12A shows a first vertical inductor 801a on the left and a second vertical inductor 802a on the right when viewed from above the substrate. The first vertical inductor 801a on the left may include a plurality of first horizontal wires 840, a plurality of second horizontal wires 860, and a plurality of first vertical wires 820 connecting the plurality of first horizontal wires 840 to the plurality of second horizontal wires 860. The second vertical inductor 802a on the right may include a plurality of third horizontal wires 842, a plurality of fourth horizontal wires 862, and a plurality of second vertical wires 822 connecting the plurality of third horizontal wires 842 to the plurality of fourth horizontal wires 862.

The first vertical inductor 801a and the second vertical inductor 802a may include a first terminal E1 and a second terminal E2, respectively, but are not limited thereto.

As shown in FIGS. 12A and 12B, in some example embodiments, the first vertical inductor 801a and the second vertical inductor 802a may share one terminal and form a three-terminal dual vertical inductor having the first terminal E1, the second terminal E2, and a common terminal E3, but the example embodiments are not limited thereto.

In some example embodiments, the dual vertical inductors shown in FIGS. 12A and 12B may be used in an RF circuit using a differential signal as input and/or a differential signal as output, but are not limited thereto. For example, the constant voltage may be applied to the common terminal E3, and the differential signal may be applied to and/or generated from the first terminal E1 and/or the second terminal E2. Also, since the double vertical inductors provides a ratio of a high inductance L to resistance, the double vertical inductors may have excellent Q-factor and may be thus used as an inductance-providing element for a high-performance and/or high-efficiency RF circuit, etc.

Next, as an example of an RF communication circuit including the vertical inductor, a voltage controlled oscillator (VCO) may be provided. The VCO or VCO circuit is an important building block in communication systems. The VCO circuit may include an LC block that includes an inductor and a capacitor and may generate a signal that oscillates at a resonance frequency that may be adjusted depending on and/or based on a desired frequency. In order to adjust the resonance frequency, the inductor and/or capacitor may be variably adjusted to match the reactance size of the inductance and/or the reactance size of the capacitance. Also, resistance loss may be compensated for by installing an amplifier in the LC circuit, etc.

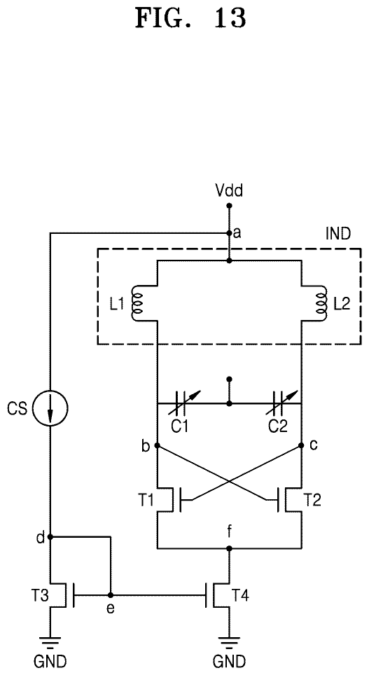

FIG. 13 is a circuit diagram of a VCO including a vertical inductor according to at least one example embodiment. Transistors shown in FIG. 13 represent n-type (or n-channel) transistors unless otherwise specified, but the example embodiments are not limited thereto.

Referring to FIG. 13, the VCO circuit may include dual vertical inductors IND described above with reference to the diagrams, but is not limited thereto. In more detail, the dual vertical inductors IND may include a first vertical inductor L1 and a second vertical inductor L2, a power supply voltage Vdd may be applied to a common node a, and a first capacitor C1 and a second capacitor C2 may be connected to the remaining nodes b and c, respectively, but the example embodiments are not limited thereto. For example, the dual vertical inductors IND may use the symmetrical dual vertical inductors described above with reference to FIGS. 12A and 12B, but is not limited thereto.

The node b may be connected to drains of the first capacitor C1 and a first transistor T1, and the node c may be connected to drains of the second capacitor C2 and a second transistor T2, etc. Also, the node b may be connected to a gate of the second transistor T2, the node c may be connected to a gate of the first transistor T1, and the voltages of the nodes b and c may mutually control the outputs of opposite transistors.

The first capacitor C1 and/or the second capacitor C2 may include a variable capacitor (e.g., the first capacitor C1 and/or the second capacitor C2 may be variable capacitors, etc.). One end of the first capacitor C1 may be connected to the node b and one end of the second capacitor C2 may be connected to the node c. Also, the first capacitor C1 and the second capacitor C2 may be connected in series between the nodes b and c.

The drain of the first transistor T1 may be connected to the first vertical inductor L1 and the first capacitor C1, and the drain of the second transistor T2 may be connected to the second vertical inductor L2 and the second capacitor C2. The sources of the first transistor T1 and the second transistor T2 are connected to a node f to form a common source.

Also, in order to supply a stable current, a current source CS that provides a constant current may be provided, and a current mirror connected to the current source CS may be provided, but the example embodiments are not limited thereto. For example, a node e corresponding to a gate of a third transistor T3 connected to the current source CS may be connected to a terminal d corresponding to a drain of the third transistor T3. A drain of a fourth transistor T4, which has a source connected to the ground GND, may be connected to a node f. Next, a gate of the fourth transistor T4 may be connected to the node e, that is, the gate of the third transistor T3. As disclosed herein, various types of RF circuits including vertical inductors may be provided.

While various example embodiments of the inventive concepts have been particularly shown and described above, it will be understood that various changes in form and details may be made therein without departing from the spirit and scope of the following inventive concepts.

1. A three-dimensional (3D) inductor comprising:
a substrate; and
at least one spiral, the at least one spiral including,
a plurality of first horizontal wires on an upper surface of the substrate,
a plurality of second horizontal wires on a back surface of the substrate, and
a plurality of vertical wires,
the plurality of vertical wires being connected to the plurality of first horizontal wires and the plurality of second horizontal wires.

2. The 3D inductor of claim 1, wherein
the plurality of first horizontal wires are at a same vertical level; and
the first horizontal wires are at least partially parallel to each other.

3. The 3D inductor of claim 1, wherein
the plurality of second horizontal wires are at a same vertical level; and
the second horizontal wires are at least partially parallel to each other.

4. The 3D inductor of claim 1, wherein the plurality of vertical wires have a same length and are parallel to each other.

5.-7. (canceled)

8. The 3D inductor of claim 1, wherein the plurality of first horizontal wires include ultra-thick metal (UTM).

9. (canceled)

10. The 3D inductor of claim 1, wherein
each of the plurality of first horizontal wires and each of the plurality of second horizontal wires each includes a connection portion connected to one of the plurality of vertical wires and a wiring portion connected to the connection portion; and
the connection portion has a width greater than a width of the wiring portion.

11. The 3D inductor of claim 1, wherein the plurality of second horizontal wires include backside metal (BSM).

12. (canceled)

13. The 3D inductor of claim 1, wherein
each of the plurality of vertical wires includes a through-silicon via (TSV); and
each of the plurality of TSVs passes through the substrate.

14.-15. (canceled)

16. The 3D inductor of claim 1, wherein the substrate further includes:
at least one insulating isolation region; and
the plurality of vertical wires pass through the at least one insulating isolation region.

17.-26. (canceled)

27. A three-dimensional (3D) inductor comprising:
a plurality of substrates including a first substrate and a second substrate stacked on each other, the first substrate at an uppermost position of the plurality of substrates and the second substrate at a lowermost position of the plurality of substrates, a rear surface of the first substrate being adjacent to a rear surface of the second substrate; and
at least one spiral, the at least one spiral including,
two terminals,
a plurality of first horizontal wires on a front surface of the first substrate;
a plurality of second horizontal wires on a front surface of the second substrate, and
a plurality of vertical wires extending in a vertical direction, the plurality of vertical wires connected to the first horizontal wires and the second horizontal wires.

28. The 3D inductor of claim 27, wherein
the plurality of first horizontal wires are at a same vertical level;
the plurality of first horizontal wires are at least partially parallel to each other;
the plurality of second horizontal wires are at a same vertical level;
the plurality of second horizontal wires are at least partially parallel to each other; and
the plurality of vertical wires have a same length.

29. The 3D inductor of claim 27, wherein the two terminals are respectively connected to two different first horizontal wires of the plurality of first horizontal wires.

30. The 3D inductor of claim 27, wherein the two terminals are respectively connected to two different second horizontal wires of the plurality of second horizontal wires.

31. The 3D inductor of claim 27, wherein each of the plurality of vertical wires includes a plurality of vertical wiring sections extending in the vertical direction.

32. The 3D inductor of claim 31, wherein each of the plurality of vertical wiring sections includes a through-silicon via (TSV) passing through the first substrate.

33. The 3D inductor of claim 31, further comprising:
at least one microbump connecting two of the plurality of vertical wiring sections to each other.

34. The 3D inductor of claim 31, wherein the plurality of vertical wiring sections are connected to each other by hybrid copper bonding (HCB).

35. The 3D inductor of claim 31, wherein the plurality of first horizontal wires and the plurality of second horizontal wires include ultra-thick metal (UTM).

36.-37. (canceled)

38. A multi-chip package comprising:
a plurality of substrates including a first substrate and a second substrate stacked on each other, the first substrate at an uppermost position of the plurality of substrates and the second substrate at a lowermost position of the plurality of substrates, a rear surface of the first substrate being adjacent to a rear surface of the second substrate;
a three-dimensional (3D) inductor including at least one spiral,
the at least one spiral including two terminals, a plurality of first horizontal wires,
a plurality of second horizontal wires, and a plurality of vertical wires,
the plurality of first horizontal wires on a front surface of the first substrate,
the plurality of second horizontal wires on a front surface of the second substrate, and
the plurality of vertical wires connected to the first horizontal wires and the second horizontal wires, the plurality of vertical wires extending in a vertical direction; and
a motherboard on which the plurality of substrates and the 3D inductor are mounted.

39. The multi-chip package of claim 38, further comprising:
at least one interposer coupled to the plurality of substrates.

40.-43. (canceled)
